(19) United States
(12) Patent Application Publication
(10) Pub. No.: US 2022/0033700 A1
(43) Pub. Date: Feb. 3, 2022

(54) NON-WATER COOLANT COMPOSITION AND COOLING SYSTEM

(71) Applicant: TOYOTA JIDOSHA KABUSHIKI KAISHA, Toyota-shi (JP)

(72) Inventors: Yasuaki KODAMA, Seto-shi (JP); Masao WATANABE, Okazaki-shi (JP); Daisuke TOKOZAKURA, Susono-shi (JP)

(21) Appl. No.: 17/345,053

(22) Filed: Jun. 11, 2021

(30) Foreign Application Priority Data
Jul. 29, 2020 (JP) 2020-128475

(51) Int. Cl. C09K 5/10; H05K 7/20

(52) U.S. Cl. CPC C09K 5/10; C09K 2205/132; H05K 7/20927; H05K 7/20872

(57) ABSTRACT

It is an object of the present disclosure to provide a non-aqueous coolant composition that is excellent in insulation property and has improved heat transfer characteristics. The embodiment is a non-water coolant composition that comprises at least one amine compound as a non-aqueous base. The amine compound is at least one selected from the group consisting of an aliphatic amine compound, an aromatic amine compound, an alkanolamine compound, an amido amine compound, an amine oxide compound, a heterocyclic amine compound, and an ether amine compound.

### CROSS REFERENCE TO RELATED APPLICATIONS

The present application claims priority from Japanese patent application JP 2020-128475 filed on Jul. 29, 2020, the entire content of which is hereby incorporated by reference into this application.

### BACKGROUND

### Technical Field

The present disclosure relates to a non-water coolant composition and a cooling system using the non-water coolant composition.

### Background Art

A vehicle with travelling motor, such as a hybrid vehicle and an electric vehicle, includes a power control unit (PCU) for appropriately controlling an electric power. The PCU includes an inverter that drives the motor, a boost converter that controls a voltage, a DC/DC converter that steps down a high voltage, and the like. The inverter or the converter includes a power card as a card-type power module that includes semiconductor devices, and the power card generates heat caused by its switching action. Therefore, the inverter and the converter are apparatuses that possibly generates heat to have a high temperature. The heat generation apparatus in the vehicle with travelling motor includes, for example, a battery in addition to the inverter and the converter. Accordingly, the vehicle with travelling motor includes a cooling system for cooling the inverter, the converter, the battery, and the like.

For example, JP 2017-017228 A discloses a configuration of a semiconductor apparatus used for an inverter of a drive system in a vehicle with travelling motor (for example, an electric vehicle or a hybrid vehicle) (FIG. 1). A semiconductor apparatus 2 of FIG. 1 is a unit where a plurality of power cards 10 and a plurality of coolers 3 are stacked. In FIG. 1, reference numeral 10 is attached to only one power card, and reference numerals to the other power cards are omitted. For showing the whole semiconductor apparatus 2, a case 31, which houses the semiconductor apparatus 2, is illustrated by dotted lines. The one power card 10 is sandwiched between the two coolers 3. An insulating plate 6a is sandwiched between the power card 10 and one of the coolers 3, and an insulating plate 6b is sandwiched between the power card 10 and the other of the coolers 3. Greases are applied between the power card 10 and the insulating plates 6a and 6b. Greases are applied also between the insulating plates 6a and 6b and the coolers 3. For easy understanding, FIG. 1 illustrates the one power card 10 and the insulating plates 6a and 6b extracted from the semiconductor apparatus 2. The power card 10 houses a semiconductor device. The power card 10 is cooled by a refrigerant passing through the cooler 3. The refrigerant is a liquid, typically water. The power cards 10 and the coolers 3 are alternately stacked, and the coolers 3 are positioned at both ends in a stacking direction of the unit. The plurality of coolers 3 are coupled by coupling pipes 5a and 5b. A refrigerant supply pipe 4a and a refrigerant discharge pipe 4b are coupled to the cooler 3 positioned at the one end in the stacking direction of the unit. The refrigerant supplied through the refrigerant supply pipe 4a is distributed to every cooler 3 through the coupling pipes 5a. The refrigerant absorbs the heat from the adjacent power card 10 while passing through each cooler 3. The refrigerant that has passed through each cooler 3 passes through the coupling pipe 5b and is discharged from the refrigerant discharge pipe 4b.

As a coolant, a nonaqueous coolant, such as a mineral oil, an aqueous coolant comprising water (for example, a mixture of ethylene glycol and water), and the like are generally used. For example, JP 2020-026471 A discloses a coolant composition that contains: (A) polyhydric alcohol; (B) water; (C) cyclohexanol; and (D) nonionic surfactant expressed in a predetermined formula and having an HLB value of 11.0 or more as an aqueous coolant. An aqueous coolant generally has a high cooling performance.

### SUMMARY

As the configuration of the semiconductor apparatus disclosed in JP 2017-017228 generally, the coolant circulates near the power cards and the batteries. Therefore, in the vehicle with travelling motor, such as the hybrid vehicle and the electric vehicle, when the coolant leaks due to an accident, the leaked coolant possibly contacts a terminal of the power card, the battery, or the like to cause a short circuit. Therefore, from an aspect to reduce the occurrence of such a secondary accident in the case of the coolant leakage, the coolant is desired to have an excellent insulation property. In this respect, the aqueous coolant, such as the generally used mixture of ethylene glycol and water and the composition described in JP 2020-026471 A, has a high conductivity and a poor insulation property. On the other hand, a non-aqueous coolant, such as a mineral oil, has an excellent insulating property. However, the non-aqueous coolant, such as a mineral oil, has a room for improvement in cooling performance, that is, heat transfer characteristics.

Therefore, the present disclosure provides a non-aqueous coolant composition that is excellent in insulation property and has improved heat transfer characteristics.

Exemplary aspects of the embodiment will be described as follows.

(1) A non-water coolant composition comprises at least one amine compound as a non-aqueous base. The amine compound is at least one selected from the group consisting of an aliphatic amine compound, an aromatic amine compound, an alkanolamine compound, an amido amine compound, an amine oxide compound, a heterocyclic amine compound, and an ether amine compound.
(2) The non-water coolant composition according to (1) in which the amine compound is the aliphatic amine compound.
(3) The non-water coolant composition according to (2) in which the aliphatic amine compound is a compound indicated by NR¹R²R³ [in the formula, R¹ is a C₆-C₂₄-alkyl, and R² and R³ are each independently hydrogen atom or a C₁-C₄-alkyl].
(4) The non-water coolant composition according to (3) in which R¹ is a C₈-C₂₀-alkyl.
(5) The non-water coolant composition according to (3) or (4) in which R² and R³ are each independent and are a C₁-C₃-alkyl.
(6) The non-water coolant composition according to any one of (1) to (5) in which the amine compound has a content of 10 mass % or more.
(7) The non-water coolant composition according to any one of (1) to (6) further comprises at least one base oil selected from a mineral oil and a synthetic oil.
(8) The non-water coolant composition according to (7) in which the amine compound has a content of 10 mass % to 90 mass %, and the base oil has a content of 10 mass % to 90 mass %.
(9) The non-water coolant composition according to (7) in which the amine compound has a content of 30 mass % to 70 mass %, and the base oil has a content of 30 mass % to 70 mass %.
(10) The non-water coolant composition according to any one of (7) to (9) in which the amine compound and the base oil have a total content of 80 mass % to 100 mass %.
(11) The non-water coolant composition according to any one of (1) to (10) in which a conductivity at 20° C. is 0.1 μS/cm or less.
(12) A cooling system, comprising the non-water coolant composition according to any one of (1) to (11) as a refrigerant.
(13) The cooling system according to (12) in which the cooling system is for cooling a heat generation apparatus mounted on a vehicle including a travelling motor.
(14) The cooling system according to (13) in which the heat generation apparatus is an inverter, a converter, a generator, a motor, or a battery.
(15) The cooling system according to (13) or (14) in which the heat generation apparatus includes a power card, and the non-water coolant composition is in physical contact with the power card.

The present disclosure can provide the nonaqueous coolant composition that is excellent in insulation property and has improved heat transfer characteristics.

### BRIEF DESCRIPTION OF THE DRAWINGS

FIG. 1 is a schematic perspective view illustrating an exemplary configuration of a semiconductor apparatus used for an inverter of a drive system in a vehicle with travelling motor.

### DETAILED DESCRIPTION

A non-water coolant composition according to the embodiment comprises at least one amine compound as a non-aqueous base, and the amine compound is at least one selected from the group consisting of an aliphatic amine compound(s), an aromatic amine compound(s), an alkanolamine compound(s), an amido amine compound(s), an amine oxide compound(s), a heterocyclic amine compound(s), and an ether amine compound(s).

The non-water coolant composition according to the embodiment is excellent in insulation property and has improved heat transfer characteristics. In particular, since the non-water coolant composition according to the embodiment is excellent in insulation property, even when the coolant leaks due to an accident or the like, a secondary accident, such as a short circuit, can be suppressed. The non-water coolant composition according to the embodiment has improved heat transfer characteristics, thereby having a high cooling performance. Therefore, the non-water coolant composition according to the embodiment is usable in a vehicle with travelling motor, such as a hybrid vehicle and an electric vehicle in some embodiments.

The non-water coolant composition according to the embodiment provides another effect as follows. The amine compound, in particular, the aliphatic amine compound has a low ion elution. Therefore, in the non-water coolant composition according to the embodiment, ions are less likely to elute from, for example, a refrigerant pipe (for example, made of rubber) used in a cooling system, and an increase in conductivity in accordance with a long use is small. Therefore, the non-water coolant composition according to the embodiment can maintain excellent low conductivity.

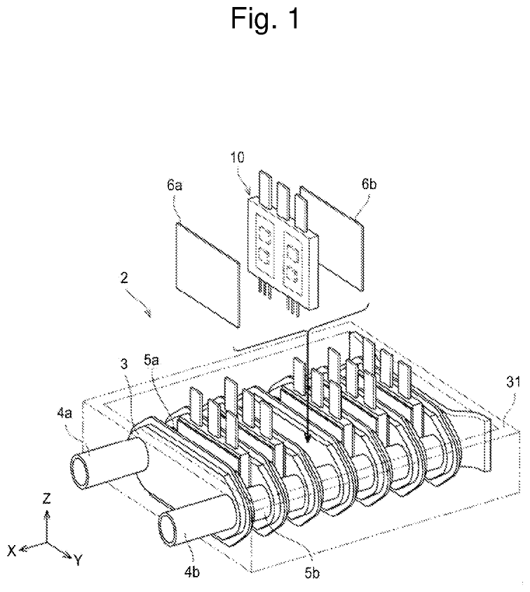

The non-water coolant composition according to the embodiment provides another effect as follows. Conventionally, a typically used ethylene glycol based aqueous coolant has excellent heat transfer characteristics but has a poor insulation property. Therefore, as illustrated in FIG. 1, a component side of a cooling object needed to have an insulation structure. Specifically, as illustrated in FIG. 1, it was necessary to dispose the insulating plates (6a and 6b of FIG. 1) to ensure the insulation between the electronic apparatus and the non-water coolant composition. However, disposing the insulating plates degrades the heat transfer characteristics between the non-water coolant composition and the electronic apparatus, thus consequently reducing the cooling performance. Since the non-water coolant composition according to the embodiment is excellent in insulation property, the disposing of the insulating plates can be eliminated, and as a result, a cooling system excellent in cooling performance can be provided.

The non-water coolant composition according to the embodiment provides another effect as follows. As an exemplary means for cooling the electronic apparatus, there has been a method to at least partially (partially or completely) immerse the electronic apparatus in the non-water coolant composition. For example, for the cooling, the power card can be disposed to be in physical contact with the non-water coolant composition. While this cooling structure has an extremely excellent heat transfer efficiency, the non-water coolant composition requires the extremely excellent insulation property because the electronic apparatus and the non-water coolant composition are in direct contact. The non-water coolant composition according to the embodiment is extremely excellent in insulation property, non-toxic, and less likely to cause corrosion. Thus, the non-water coolant composition according to the embodiment is usable in the cooling system that has this cooling structure in some embodiments.

The following describes the embodiment in detail.

### 1. Non-Water Coolant Composition

The non-water coolant composition according to the embodiment is non-aqueous. In this description, non-aqueous means substantially free of water, “substantially free of water” means that the non-water coolant composition does not comprise water in a content range in which expression of the effect of the embodiment is interfered, means that the water content in the non-water coolant composition is 1.0 mass % or less in some embodiments, means that the water content in the non-water coolant composition is 0.5 mass % or less in some embodiments, means that the water content in the non-water coolant composition is 0.1 mass % or less in some embodiments, means that the water content in the non-water coolant composition is 0.01 mass % or less in some embodiments, or means that the water content in the non-water coolant composition is 0 mass % (undetectable) in some embodiments.

The non-water coolant composition according to the embodiment comprises at least one amine compound as a non-aqueous base, and the amine compound is at least one selected from the group consisting of an aliphatic amine compound, an aromatic amine compound, an alkanolamine compound, an amido amine compound, an amine oxide compound, a heterocyclic amine compound, and an ether amine compound. The amine compound is free of fluorine atoms in some embodiments. The amine compound is excellent in insulation property and heat transfer characteristic. One amine compound may be used alone, or 2 or more amine compounds may be used in combination.

In one embodiment, the amine compound is an aliphatic amine compound. The aliphatic amine compound is excellent in insulation property and heat transfer characteristic, and the aliphatic amine compound has a low ion elution, thereby allowing suppressed ion elution from the refrigerant pipe (for example, made of rubber). As a result, the aliphatic amine compound can maintain excellent low conductivity.

The aliphatic amine compound may be a saturated aliphatic amine compound or may be an unsaturated aliphatic amine compound. The unsaturated aliphatic amine compound comprises at least one unsaturated bond. The aliphatic amine compound may be a primary amine, may be a secondary amine, or may be a tertiary amine. In the secondary amine and tertiary amine, each hydrocarbon is independent, and each of them may be the same or may be different. Hydrocarbon groups in the aliphatic amine compound are each independent, and may be linear or may be branched chain. The hydrocarbon group in the aliphatic amine compound has, for example, 1 to 24 carbon atoms, and at least one hydrocarbon group have 6 to 24 carbon atoms in some embodiments. One aliphatic amine compound may be used alone or 2 or more aliphatic amine compounds may be used in combination.

In one embodiment, the aliphatic amine compound is a compound indicated by NR¹R²R³ [in the formula, R¹ is a C₆-C₂₄-alkyl, and R² and R³ are each independently hydrogen atom or a C₁-C₄-alkyl]. In the formula, R¹ is a C₈-C₂₀-alkyl, is a C₁₀-C₁₈-alkyl, and is a C₁₂-C₁₆-alkyl in some embodiments. In the formula, R² and R³ are each independently a C₁-C₃-alkyl and a C₁-C₂-alkyl in some embodiments. In the formula, the alkyl may be linear or may be branched chain.

The aliphatic amine includes, for example, octylamine, nonylamine, decylamine, undecylamine, dodecylamine (laurylamine), tridecylamine, tetradecylamine, pentadecylamine, hexadecylamine, heptadecylamine, octadecylamine (stearylamine), and an amine in which one or both of two hydrogens bonding to a nitrogen atom in these compounds are replaced by methyl or ethyl.

In one embodiment, the amine compound is an aromatic amine compound. The aromatic amine compound includes, for example, aniline, benzylamine, m-xylylenediamine, or diaminodiphenylmethane. One aromatic amine compound may be used alone or 2 or more aromatic amine compounds may be used in combination.

In one embodiment, the amine compound is an alkanolamine compound. The alkanolamine compound includes, for example, aminomethyl propanol, diglycolamine, methanolamine, monoisopropylamine, diethanolamine, diisopropanolamine, N-butylethanolamine, triethanolamine, or N-butyldiethanolamine. One alkanolamine compound may be used alone or 2 or more alkanolamine compounds may be used in combination.

In one embodiment, the amine compound is an amido amine compound. The amido amine compound includes, for example, stearamidopropyl dimethylamine, stearamidopropyl diethylamine, stearamidoethyl diethylamine, stearamidoethyl dimethylamine, or stearyl amidopropyl dimethylamine. One amido amine compound may be used alone or 2 or more amido amine compounds may be used in combination.

In one embodiment, the amine compound is an amine oxide compound. The amine oxide compound includes, for example, lauryldimethylamine oxide or dodecyldimethylamine oxide. One amine oxide compound may be used alone or 2 or more amine oxide compounds may be used in combination.

In one embodiment, the amine compound is a heterocyclic amine compound. The heterocyclic amine compound includes, for example, pyridine. One heterocyclic amine compound may be used alone or 2 or more heterocyclic amine compounds may be used in combination.

In one embodiment, the amine compound is an ether amine compound. The ether amine compound includes, for example, monoalkyl (C8-C22) ether amine. One ether amine compound may be used alone or 2 or more ether amine compounds may be used in combination.

The amine compound has a melting point of 0° C. or less, and has a melting point of −35° C. or less in some embodiments.

The amine compound has a molecular weight within a range of 120 to 300, a molecular weight within a range of 130 to 270, and a molecular weight within a range of 150 to 250 in some embodiments. When the molecular weight of the amine compound is within these ranges, a viscosity increase is suppressed, thereby allowing keeping cooling capability.

A content of the amine compound in the non-water coolant composition is, for example, 10 mass % or more, 20 mass % or more in some embodiments, 30 mass % or more in some embodiments, 40 mass % or more in some embodiments, and 50 mass % or more in some embodiments. The more the content of the amine compound is, the more the insulation property and the heat transfer characteristics of the non-water coolant composition can be improved. The content of the amine compound in the non-water coolant composition is, for example, 100 mass % or less, and is 90 mass % or less in some embodiments. The content of the amine compound in the non-water coolant composition could be 100 mass %.

The non-water coolant composition according to the embodiment may comprise at least one other non-aqueous base other than the above-described amine compound. The at least one other non-aqueous base is at least one base oil selected from a mineral oil and a synthetic oil in some embodiments. That is, in one embodiment, the non-water coolant composition comprises at least one base oil selected from a mineral oil and a synthetic oil in addition to the above-described amine compound as a non-aqueous base. Selecting the at least one base oil as at least one other non-aqueous base allows an improved insulation property of the non-water coolant composition. The base oil and the amine compound have high compatibility, and therefore, it is less likely to cause a problem of phase separation and the like even when they are mixed. Therefore, the non-water coolant composition comprising the amine compound and the base oil is a coolant with high insulating property and satisfactory stability as a liquid composition. The mineral oil includes, for example, a paraffin mineral oil, a naphthenic mineral oil, or a mixture of them. The synthetic oil includes, for example, an ester synthetic oil, a synthetic hydrocarbon oil, a silicone oil, a fluorinated oil, or a mixture of them. One base oil may be used alone or 2 or more base oils may be used in combination.

A kinematic viscosity (40° C.) of the base oil is not specifically limited. It is, for example, 0.5 mm²/s to 100 mm²/s, 0.5 mm²/s to 20 mm²/s in some embodiments, and 0.5 mm²/s to 10 mm²/s in some embodiments.

The content of the base oil in the non-water coolant composition is 10 mass % or more in some embodiments, 20 mass % or more in some embodiments, 30 mass % or more in some embodiments, 40 mass % or more in some embodiments, and 50 mass % or more in some embodiments.

When the non-water coolant composition comprises the base oil, the content of the amine compound in the non-water coolant composition is 10 mass % to 90 mass % and the content of the base oil in the non-water coolant composition is 10 mass % to 90 mass % in some embodiments. When the non-water coolant composition comprises the base oil, the content of the amine compound in the non-water coolant composition is 30 mass % to 70 mass % and the content of the base oil in the non-water coolant composition is 30 mass % to 70 mass % in some embodiments. When the non-water coolant composition comprises the base oil, the content of the amine compound in the non-water coolant composition is 40 mass % to 60 mass % and the content of the base oil in the non-water coolant composition is 40 mass % to 60 mass % in some embodiments.

When the non-water coolant composition comprises the base oil, the total content of the amine compound and the base oil in the non-water coolant composition is 80 mass % or more in some embodiments, 85 mass % or more in some embodiments, 90 mass % or more in some embodiments, 95 mass % or more in some embodiments, 98 mass % or more in some embodiments, or 100 mass % in some embodiments.

The non-water coolant composition according to the embodiment may comprise at least one additive, such as an antioxidant agent, a rust inhibitor, a friction modifier, an anticorrosive, a viscosity index improver, a pour point depressant, a dispersing agent/surfactant, an antiwear agent, or a solid lubricant, in addition to the above-described components. The content of the at least one additive in the non-water coolant composition is, for example, 0.1 to 20 mass %, and is 10 mass % or less in some embodiments, 5 mass % or less in some embodiments, and 1 mass % or less in some embodiments.

A kinematic viscosity (20° C.) of the non-water coolant composition according to the embodiment is, for example, 0.1 mm²/s to 100 mm²/s, and is 0.1 mm²/s to 10 mm²/s in some embodiments.

Since the non-water coolant composition is forcibly circulated in the cooling system, the viscosity is lowered in some embodiments. The viscosity of the non-water coolant composition can be adjusted by, for example, a viscosity and an amount of the base oil to be added. The kinematic viscosity (40° C.) of the non-water coolant composition according to the embodiment is 0.1 mm²/s to 10 mm²/s in some embodiments.

A conductivity (20° C.) of the non-water coolant composition according to the embodiment is 0.1 μS/cm or less in some embodiments, 0.01 μS/cm or less in some embodiments, and 0.001 μS/cm or less in some embodiments.

### 2. Cooling System

The non-water coolant composition according to the embodiment is used for the cooling system, and is used for the cooling system mounted on a vehicle with travelling motor in some embodiments. That is, an aspect of the embodiment is a cooling system where the non-water coolant composition according to the embodiment is used as a refrigerant. An aspect of the embodiment is a cooling system for cooling a heat generation apparatus mounted on a vehicle with travelling motor. An aspect of the embodiment is a vehicle with travelling motor that includes the cooling system according to the embodiment and the heat generation apparatus cooled by the cooling system.

The “vehicle with travelling motor” in this description includes both an electric vehicle and a hybrid vehicle. The electric vehicle includes only a travelling motor as a power source without an engine. The hybrid vehicle includes both the travelling motor and the engine as the power source. A fuel cell vehicle is also included in the “vehicle with travelling motor.”

As one of the environmental measures, the vehicle with travelling motor, such as the hybrid vehicle, the fuel cell vehicle, and the electric vehicle, that travels by a driving force of the motor has attracted attention. In this type of vehicle, since the heat generation apparatus, such as a motor, a generator, an inverter, a converter, and a battery, generates a heat to have a high temperature, the heat generation apparatus needs to be cooled. As described above, the non-water coolant composition according to the embodiment has a combination of excellent insulation property and heat transfer characteristics. Therefore, a secondary accident, such as a short circuit, is less likely to occur even when the non-water coolant composition leaks due to an accident or the like. In addition, the non-water coolant composition according to the embodiment is excellent in cooling performance. Therefore, the non-water coolant composition according to the embodiment is usable for the cooling system of the vehicle with travelling motor in some embodiments.

The cooling system includes, for example, a refrigerant pipe through which the non-water coolant composition as a refrigerant flows, a reservoir tank that houses the non-water coolant composition, a circulation device for circulating the non-water coolant composition in a circulation passage, or a cooling device for decreasing the temperature of the non-water coolant composition. The circulation device includes, for example, an electric pump. The cooling device includes, for example, a radiator, a chiller, or an oil cooler. A cooling object for the cooling system is the heat generation apparatus, such as the inverter, the converter, the generator, the motor, or the battery.

The configuration of the cooling system is not specifically limited. The cooling system includes, for example, the refrigerant pipe, the reservoir tank, the electric pump, the radiator, and a cooling unit included in the heat generation apparatus. The cooling unit is a unit to receive a heat from the heat generation apparatus, and for example, the cooler 3 of FIG. 1 corresponds to the cooling unit. For example, after the non-water coolant composition is pumped up from the reservoir tank by the electric pump, the heat generation apparatus is cooled by the cooling unit, and subsequently, the non-water coolant composition is returned to the reservoir tank via the radiator on a downstream side. Since the temperature of the non-water coolant composition that has cooled the cooling unit rises, the temperature of the non-water coolant composition that has risen in temperature is decreased by the radiator. A configuration where the oil cooler is disposed on the way of the refrigerant pipe to cool the motor by this oil cooler can be employed.

The cooling system according to the embodiment is used for the vehicle with travelling motor in some embodiments. That is, an aspect of the embodiment is a vehicle with travelling motor that includes the cooling system according to the embodiment. An aspect of the embodiment is an electric vehicle, a hybrid vehicle, or a fuel cell vehicle that includes the cooling system according to the embodiment.

As described above, the non-water coolant composition according to the embodiment is extremely excellent in insulation property, non-toxic, and less likely to cause corrosion. Thus, the non-water coolant composition according to the embodiment is usable for the cooling system that has a cooling structure where the electronic apparatus is at least partially (partially or completely) immersed in the non-water coolant composition in some embodiments. The electronic apparatus includes, for example, a power card and a CPU, which include semiconductor devices. Specific configurations of this cooling system can be found in, for example, U.S. Pat. No. 7,403,392 or US Patent Application Publication No. 2011-0132579 A. Specifically, an aspect of the embodiment is the vehicle with travelling motor where the heat generation apparatus includes the power card, and the non-water coolant composition is in physical contact with the power card.

### EXAMPLES

While the following describes the embodiment with examples, the disclosure is not limited to the examples.

### <Material>

N,N-dimethyldecylamine (manufactured by Tokyo Chemical Industry)
N,N-dimethyldodecylamine (manufactured by Tokyo Chemical Industry)
3-aminobenzotrifluoride (manufactured by Tokyo Chemical Industry)
Mineral oil: kinematic viscosity (20° C.) 0.1 mm²/s to 10 mm²/s
Conventional LLC (Toyota genuine, product name: Super Long-Life Coolant, including ethylene glycol and additive)
Ethylene glycol (manufactured by Tokyo Chemical Industry) (hereinafter also referred to as EG)
Ion exchanged water

### <Preparation Method>

Respective non-water coolant compositions were prepared with compositions described in Table 1 and Table 2 below.

### <Conductivity>

The conductivities of the respective non-water coolant compositions at 20° C. were measured using a conductivity measuring machine (manufactured by Yokogawa Electric Corporation, SC72 Personal Handheld Conductivity Meter, sensor: SC72SN-11). Table 1 and Table 2 indicate the results.

### <Heat Transfer Characteristics>

The heat transfer characteristics of the respective non-water coolant compositions were compared by calculating the cooling performances of the radiators, which used the respective non-water coolant compositions as the refrigerants, with formulas below. Table 1 and Table 2 indicate the results.

Specifically, the cooling performances in the radiators using the respective non-water coolant compositions as the refrigerants were calculated with the formula below. The refrigerants were adjusted to have inlet temperatures at 65° C. Other conditions were as follows. Ventilation volume to radiator: 4.5 m/sec, refrigerant flow rate: 10 L/min, temperature difference between refrigerant and external air: 40° C. (refrigerant: 65° C., external air: 25° C.).

$${Q}_{w} = \frac{{V}_{w} \cdot {γ}_{w} \cdot {10}^{- 3}}{60} \cdot {C}_{pw} \cdot ( {T}_{w 1} - {t}_{w 2} ) \qquad [ Math . 1 ]$$

Q^{W}: cooling performance, V_{W}: refrigerant flow rate, γ_{W}: refrigerant density, C_{PW}: refrigerant specific heat, t_{W1}: refrigerant inlet temperature, t_{W2}: refrigerant outlet temperature

<Compatibility>

To confirm the compatibility between the amine compound and the mineral oil, the respective non-water coolant compositions of Examples 3 to 6 and Comparative Example 5 were put in beakers, after stirring for five minutes at room temperature with a stirrer, were allowed to stand for 24 hours. Subsequently, presence/absence of phase separation was observed. Table 1 and Table 2 indicate the results. Note that, in Table 1 and Table 2, a case where the phase separation did not occur is indicated by “Good” and a case where the phase separation did occur is indicated by “Poor.”

TABLE 1

| | | Example | Example | Example | Example | Example | Example |
|---|---|---|---|---|---|---|---|
| | Component | 1 | 2 | 3 | 4 | 5 | 6 |
| Composition | N,N- | 100 | — | 50 | — | 10 | — |
| (Mass %) | Dimethyldecylamine | | | | | | |
| | N,N- | — | 100 | — | 50 | — | 10 |
| | Dimethyldodecylamine | | | | | | |
| | 3-Aminobenzotrifluoride | — | — | — | — | — | — |
| | Conventional LLC | — | — | — | — | — | — |
| | (EG + Additive) | | | | | | |
| | Ethylene Glycol | — | — | — | — | — | — |
| | Mineral Oil | — | — | 50 | 50 | 90 | 90 |
| | Ion Exchanged Water | — | — | — | — | — | — |
| Sum | | 100 | 100 | 100 | 100 | 100 | 100 |
| Evaluation | Conductivity | <0.0009 | <0.0009 | <0.0009 | <0.0009 | <0.0009 | <0.0009 |
| | Cooling Performance | 225 | 215 | 213 | 208 | 199 | 198 |
| | (Radiator) | | | | | | |
| | Compatibility | — | — | Good | Good | Good | Good |

TABLE 2

| | | Comparative | Comparative | Comparative | Comparative | Comparative |
|---|---|---|---|---|---|---|
| | | Example | Example | Example | Example | Example |
| | Component | 1 | 2 | 3 | 4 | 5 |
| Composition | N,N- | — | — | — | — | — |
| (Mass %) | Dimethyldecylamine | | | | | |
| | N,N- | — | — | — | — | — |
| | Dimethyldodecylamine | | | | | |
| | 3-Aminobenzotrifluoride | — | — | — | — | 50 |
| | Conventional LLC | 50 | — | — | — | — |
| | (EG + Additive) | | | | | |
| | Ethylene Glycol | — | 50 | — | — | — |
| | Mineral Oil | — | — | 100 | | 50 |
| | Ion Exchanged Water | 50 | 50 | — | 100 | — |
| Sum | | 100 | 100 | 100 | 100 | 100 |
| Evaluation | Conductivity | 7000 | 0.6 | <0.0009 | 0.3 | <0.0009 |
| | Cooling Performance | 371 | 368 | 197 | 458 | — |
| | (Radiator) | | | | | |
| | Compatibility | — | — | — | — | Poor |

The non-water coolant compositions in all Examples had conductivities of less than 0.0009 μS/cm, and therefore, were excellent in insulation property. The non-water coolant compositions in all Examples had cooling performances higher than the cooling performance of the mineral oil (Comparative Example 3), and therefore, it was confirmed that they had improved heat transfer characteristics. In particular, as the content of the amine compound increased, the cooling performance improved.

On the other hand, Comparative Examples 1, 2, and 4 that had compositions (mixture of ethylene glycol and water or water alone) of conventional non-water coolant compositions had increased conductivities, and therefore, were insufficient in insulation property. In the example using the 3-aminobenzotrifluoride in Comparative Example 5, the phase separation was caused between the 3-aminobenzotrifluoride and the mineral oil, and a uniform liquid composition could not be obtained.

From the results described above, it was proved that the non-water coolant compositions according to the embodiment were excellent in insulation property and had improved in heat transfer characteristics.

Terms used in the Description should be understood as used with meanings usually used in the technical field unless otherwise stated. Accordingly, unless otherwise defined differently, all the technical terms and the science and technology terms used in the Description have the same meanings as terms generally understood by a person skilled in the art pertaining to the present disclosure. In the case of inconsistency, the Description (including definition) has priority.

It should be understood that throughout the entire Description, the expression as a singular form also includes a concept of its plural form unless otherwise stated. Accordingly, articles of a singular form (for example, in the case of English, “a,” “an,” and “the”) should be understood as including the concept of its plural form unless otherwise stated.

Upper limit values and/or lower limit values of respective numerical ranges described in this description can be appropriately combined to specify an intended range. For example, upper limit values and lower limit values of the numerical ranges can be appropriately combined to specify an intended range, upper limit values of the numerical ranges can be appropriately combined to specify an intended range, and lower limit values of the numerical ranges can be appropriately combined to specify an intended range.

While the embodiment has been described in detail, the specific configuration of the disclosure is not limited to the embodiment. Design changes within a scope not departing from the gist of the disclosure are included in the disclosure.

What is claimed is:

1. A non-water coolant composition comprising
at least one amine compound as a non-aqueous base,
wherein the amine compound is at least one selected from the group consisting of an aliphatic amine compound, an aromatic amine compound, an alkanolamine compound, an amido amine compound, an amine oxide compound, a heterocyclic amine compound, and an ether amine compound.

2. The non-water coolant composition according to claim 1,
wherein the amine compound is the aliphatic amine compound.

3. The non-water coolant composition according to claim 2,
wherein the aliphatic amine compound is a compound indicated by NR¹R²R³ [in the formula, R¹ is a C₆-C₂₄-alkyl, and R² and R³ are each independently hydrogen atom or a C₁-C₄-alkyl].

4. The non-water coolant composition according to claim 3,
wherein R¹ is a C₈-C₂₀-alkyl.

5. The non-water coolant composition according to claim 3,
wherein R² and R³ are each independently a C₁-C₃-alkyl.

6. The non-water coolant composition according to claim 1,
wherein the amine compound has a content of 10 mass % or more.

7. The non-water coolant composition according to claim 1, further comprising
at least one base oil selected from a mineral oil and a synthetic oil.

8. The non-water coolant composition according to claim 7,
wherein the amine compound has a content of 10 mass % to 90 mass %, and
wherein the base oil has a content of 10 mass % to 90 mass %.

9. The non-water coolant composition according to claim 7,
wherein the amine compound has a content of 30 mass % to 70 mass %, and
wherein the base oil has a content of 30 mass % to 70 mass %.

10. The non-water coolant composition according to claim 7,
wherein the amine compound and the base oil have a total content of 80 mass % to 100 mass %.

11. The non-water coolant composition according to claim 1,
wherein the non-water coolant composition has a conductivity at 20° C. is 0.1 μS/cm or less.

12. A cooling system, comprising the non-water coolant composition according to claim 1 as a refrigerant.

13. The cooling system according to claim 12,
wherein the cooling system is for cooling a heat generation apparatus mounted on a vehicle including a travelling motor.

14. The cooling system according to claim 13,
wherein the heat generation apparatus is an inverter, a converter, a generator, a motor, or a battery.

15. The cooling system according to claim 13,
wherein the heat generation apparatus includes a power card, and the non-water coolant composition is in physical contact with the power card.
